(19) United States
(12) Patent Application Publication
(10) Pub. No.: US 2015/0101848 A1
(43) Pub. Date: Apr. 16, 2015

(54) SURFACE-TREATED COPPER FOIL AND COPPER-CLAD LAMINATE PLATE INCLUDING THE SAME, PRINTED CURCUIT BOARD USING THE SAME, AND METHOD FOR MANUFACTURING THE SAME

(71) Applicant: SAMSUNG ELECTRO-MECHANICS CO., LTD., Suwon-Si (KR)

(72) Inventors: Ji Sung CHO, Suwon-Si (KR); Toshiko Yokota, Suwon-Si (KR); Makoto Dobashi, Suwon-Si (KR); Seung Min Baek, Suwon-Si (KR); Ichiro Ogura, Suwon-Si (KR); Eun Jung Lim, Suwon-Si (KR); Yoon Su Kim, Suwon-Si (KR); Sung Han, Suwon-Si (KR)

(73) Assignee: SAMSUNG ELECTRO-MECHANICS CO., LTD., Suwon-Si (KR)

(21) Appl. No.: 14/491,888

(22) Filed: Sep. 19, 2014

(30) Foreign Application Priority Data
Oct. 10, 2013 (KR) 10-2013-0120775
May 9, 2014 (KR) 10-2014-0055802

(51) Int. Cl. H05K 1/02; H05K 1/09; H05K 3/00; H05K 1/03

(52) U.S. Cl. CPC H05K 1/0284; H05K 1/0333; H05K 1/09; H05K 3/007; H05K 2201/0335; H05K 2203/0369
USPC 174/255; 428/457; 428/337; 428/419; 428/422; 428/448; 428/336; 216/20

(57) ABSTRACT

Disclosed herein are a surface-treated copper foil, a copper-clad laminate plate including the same, a printed circuit board using the same, and a method for manufacturing the same. In detail, the copper-clad laminate plate according to one implementation embodiment of the present invention includes: carrier; a peel layer formed on the carrier; a copper-clad layer formed on the peel layer; and a surface-treated layer formed on the copper-clad layer, in which the surface-treated layer includes a thiol-based compound. Therefore, the present invention provides a printed circuit board capable of improving an adhesive force between a base and a copper-clad layer without treating a roughed surface by forming the surface-treated layer on the copper-clad layer.

### CROSS REFERENCE TO RELATED APPLICATION

This application claims the benefit of Korean Patent Application No. 10-2013-0120775, filed on Oct. 10, 2013, entitled “Surface-Treated Copper Foil And Copper-Clad Laminate Plate Comprising The Same And Printed Circuits Board Used Of The Surface-Treated Copper Foil” and Korean Patent Application No. 10-2014-0055802, filed on May 9, 2014, entitled “Surface-Treated Copper Foil, Copper Clad Laminate Comprising The Same, Printed Circuit Board Using The Same, And Manufactured Method Thereof”, which are hereby incorporated by reference in their entireties into this application.

### BACKGROUND OF THE INVENTION

1. Technical Field

The present invention relates to a surface-treated copper foil, a copper-clad laminate plate including the same, a printed circuit board using the same, and a method for manufacturing the same.

2. Description of the Related Art

With the electronic device trend toward miniaturization and high performance, a demand for a high-density, multi-functional, small, and thin multilayered printed circuit board has increased. Therefore, the printed circuit board on which various electronic components are mounted has been finely patterned.

With the recently rapid advancement of IT technologies, a demand for high-performance, multi-functional, and small electronic devices, such as a portable terminal device, a computer, and a display has rapidly increased. Therefore, electronic components, such as a semiconductor device used in the electronic devices and a board on which these electronic components are mounted also tend to be multi-functional and high-performance.

In particular, to develop a fine and high-density wiring, instead of a method for forming an insulating layer having a prepreg type in which a glass cloth is impregnated, a method for forming a circuit by building-up an insulating film without the glass cloth using an SAP or MSAP scheme has increased. Further, a build-up layer of the multilayered printed circuit board has been multilayered.

For example, in connection with a flexible printed wiring board (hereinafter, referred to as FPC), a wiring pattern needs to be thinned, multilayered, and the like. Today, a component mounting FPC in which components are mounted on the FPC, a double-sided FPC in which circuits are formed on double sides, a multilayered FPC forming an interlayer wiring by stacking a plurality of FPCs, and the like has emerged. Therefore, a material forming the FPC having higher thinness and dimensional stability is required.

Currently, as a copper foil used in electronic industry fields, a thin copper plating foil formed by plating a carrier of a copper or aluminum foil having a thickness of 18 μm to 35 μm at a thickness of 1 to 5 μm has been used. Further, a light, thin, small, and fine copper plating foil has been required to be used as a fine circuit in electrical components of a high-density printed circuit board, precise printed wiring circuit components for a board, and the like.

According to the prior art, in order to increase plating adhesion between a copper-clad layer and an insulating layer, a desmear (roughening plating) process forming a roughed surface by etching a surface of the insulating layer with potassium permanganate, and the like has been conducted. Further, an attempt to increase an adhesive strength between the insulating layer and the copper-clad layer by exhibiting an anchor effect of the insulating layer on the roughed surface has been conducted. However, there is a limitation in thinly forming a thickness of the copper foil due to a formation size of a roughed surface formed on the insulating layer.

In other words, when a thin copper foil adheres to the roughed surface, the copper foil is likely to be torn and may have a weak mechanical strength due to a thin thickness thereof.

Therefore, for implementation of a fine and high-density wiring, a method for securing the adhesive force between the insulating layer and the copper-clad layer while keeping the thickness of the copper-clad layer to be thin is required.

Therefore, the present invention provides a surface-treated copper foil, a copper-clad laminate plate including the same, a printed circuit board using the same, and a method for manufacturing the same, in which the surface-treated copper foil includes a copper-clad layer and a surface-treated layer which is formed on the copper-clad layer, the copper-clad laminate plate including the same, the printed circuit board using the same, and the method for manufacturing the same show the high adhesive strength while maintaining a thin copper-clad layer. The present invention is completed based thereon.

Patent Document 1: Korean Patent Laid-Open Publication No. 2007-0017547

### SUMMARY OF THE INVENTION

The present invention has been made in an effort to provide a surface-treated copper foil capable of exhibiting an anchor effect without needing to treat a roughed surface by surface-treating a copper-clad layer.

Further, the present invention has been made in an effort to provide a copper-clad laminate plate capable of forming a thin copper-clad layer by using the surface-treated copper foil.

In addition, the present invention has been made in an effort to provide a printed circuit board having a fine line width and a fine pitch while improving an adhesive strength of an insulating layer and a thin circuit layer by stacking the copper-clad laminate plate on the insulating layer to form a thin circuit layer, and a method for manufacturing the same.

According to an implementation embodiment of the present invention, there is provided a surface-treated copper foil, including: a copper-clad layer; and a surface-treated layer formed on the copper-clad layer.

A thickness of the copper-clad layer may range from 0.1 μm to 5 μm.

The surface-treated layer may include a thiol-based compound.

According to another implementation embodiment of the present invention, there is provided a copper-clad laminate plate, including: a carrier; a peel layer formed on the carrier; a copper-clad layer formed on the peel layer; and a surface-treated layer formed on the copper-clad layer.

The carrier made of polymer may be selected from poly (ethyleneterephthalate) (PET), poly (phenylenesulfide) (PPS), Teflon, and fluorine containing film.

A thickness of the carrier made of the polymer may range from 15 μm to 200 μm.

The carrier made of the metals may be selected from copper, aluminum, or a combination thereof.

The thickness of the carrier made of the metal may range from 10 μm to 30 μm.

The peel layer may be selected from a silicon-based compound, an azole-based compound, or a mixture thereof.

The thickness of the copper-clad layer may range from 0.1 to 5 μm.

The surface-treated layer may include a thiol-based compound.

According to still another implementation embodiment of the present invention, there is provided a printed circuit board, including: an insulating layer; a surface-treated layer formed on the insulating layer; and a circuit pattern formed on the surface-treated layer.

The surface-treated layer may include a thiol-based compound.

A thickness of the circuit pattern may range from 0.1 μm to 5 μm.

A peel strength of the surface-treated layer and the insulating layer may be 0.6 kgf/cm or more.

An epoxy resin used for the insulating layer may be at least one selected from naphthalene-based epoxy resin, bisphenol A type epoxy resin, phenol novolac epoxy resin, cresol novolac epoxy resin, rubber modified epoxy resin, phosphate epoxy resin, and bisphenol F type epoxy resin.

According to still yet another implementation embodiment of the present invention, there is provided a method for manufacturing a printed circuit board, including: adhering an insulating layer to a copper-clad laminate plate including a carrier, a peel layer, a copper-clad layer, and a surface-treated layer; peeling the carrier and the peel layer of the copper-clad laminate plate; and patterning the copper-clad layer and the surface-treated layer of the copper-clad laminate plate.

The patterning of the copper-clad layer and the surface-treated layer of the copper-clad laminate plate may include: applying a photoresist on the copper-clad layer; forming an opening by exposing and developing a portion of the applied photoresist film; and etching the copper-clad layer and the surface-treated layer of an area in which the opening is formed.

The copper-clad layer may be formed by at least any one process selected from sputter, electronic beam, chemical vapor deposition (CVD), physical vapor deposition (PVD), vacuum deposition, ion plating, and plasma deposition.

The peel layer may be made of a solution including a silicon-based compound, an azole-based compound, or a combination thereof from a process selected by any one of an immersion method, a showering method, and a spray method.

A thickness of the copper-clad layer may range from 0.1 μm to 5 μm.

A peel strength of the surface-treated layer and the insulating layer may be 0.6 kgf/cm or more.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional view of a surface-treated copper foil according to one implementation embodiment of the present invention;

FIG. 2 is a diagram illustrating a surface-treated layer of a surface-treated copper foil according to the one implementation embodiment of the present invention;

FIG. 3 is a diagram illustrating a copper-clad laminate plate according to according to the one implementation embodiment of the present invention;

FIG. 4 is a diagram illustrating a printed circuit board according to the one implementation embodiment of the present invention; and

FIGS. 5A to 5E are process diagrams illustrating a method for manufacturing a printed circuit board according to the one implementation embodiment of the present invention.

### DESCRIPTION OF THE IMPLEMENTATION EMBODIMENTS

The objects, features and advantages of the present invention will be more clearly understood from the following detailed description of the implementation embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, implementation embodiments of the present invention will be described in detail with reference to the attached drawings.

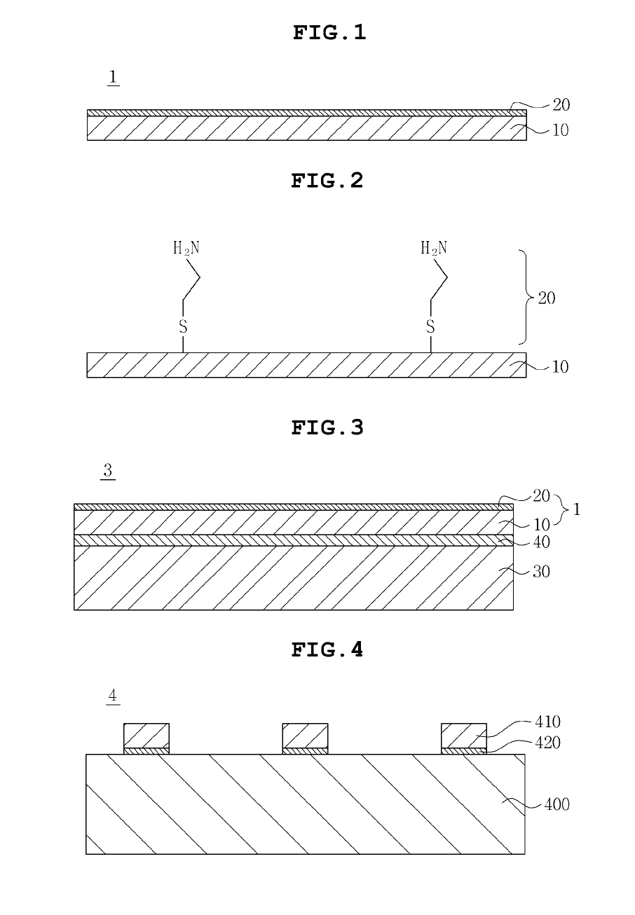

FIG. 1 is a cross-sectional view of a surface-treated copper foil according to one implementation embodiment of the present invention and FIG. 2 is a diagram illustrating a surface-treated layer of a surface-treated copper foil according to the one implementation embodiment of the present invention.

Referring to FIGS. 1 and 2, a surface-treated copper foil 1 according to the one implementation embodiment of the present invention includes a copper-clad layer 10 and a surface-treated layer 20 which is formed on the copper-clad layer 10. In this configuration, the surface-treated layer 20 may include a thiol-based compound.

A thickness of the copper-clad layer 10 may range from 0.1 μm to 5 μm. When the thickness of the copper-clad layer 10 is less than 0.1 μm, microporosity may occur on the copper-clad layer 10 and when the thickness of the copper-clad layer 10 exceeds 5 μm, the copper-clad layer 10 may not have required basic qualities. As described above, a fine circuit pattern and a fine pitch may be implemented by using the copper-clad layer 10 of which the thickness is formed thinly.

The surface-treated layer 20 may be formed on one surface of the copper-clad layer 10. The surface-treated layer 20 improves wettability with a base which adheres to the surface-treated layer 20, thereby improving the adhesive force with the base.

To improve the adhesive force, the surface-treated layer 20 may form the surface-treated layer 20 on a surface of the copper-clad layer 10 using a thiol-based compound.

To form the surface-treated layer 20, an adsorption time of 2 hours to 4 hours is required. The surface-treated layer 20 may be formed, for example, as self assembled monolayers (SAMs). The self assembled monolayers may be coupled with a surface of solid by spontaneously forming an integrated thin film having a nano size on a surface of solid.

For example, since polyimide and copper used for a wiring formed of the insulating layer and the copper-clad layer of the printed circuit board are different from each other in terms of resin and metal, the polyimide and the copper may not adhere to each other as they are. Therefore, according to the prior art, when making the surfaces rough (forming an anchor) and applying an adhesive on the surfaces to bond the surfaces, the adhesive penetrates into a fine roughness of the adhering portion and is cured in this state, thereby obtaining the adhesive force.

However, in the case of forming a wiring layer of a thin copper-clad layer, when a to roughness surface is formed on the copper-clad layer, the copper-clad layer may be torn.

Therefore, according to the one implementation embodiment of the present invention, the surface-treated layer 20 formed of the self assembled monolayers may be formed on the copper-clad layer 10 using the thiol-based compound and then may be pressed or adhere to a base which may be bonded to the copper-clad layer 10 to give heat energy, thereby improving an adhesion between the surface-treated layer 20 and the base.

To describe in more detail this, referring to FIG. 2, the surface-treated layer 20 may have a functional group reacting to a metal atom on a surface of the substrate to form the self assembled monolayers on the surface of the copper-clad layer 10. Further, to form the surface-treated layer 20, it is preferable to use the surface treating agent which may form a high-density thin film which is aggregated by the self assembled monolayers. Further, the surface treating agent preferably has intermolecular interaction.

Thiol derivatives of the thiol-based compound forming the self assembled monolayers according to the one implementation embodiment of the present invention are thiol (—SH) and disulfide (—S—S) as a functional group, in which sulfur and copper (Cu—S) may be covalently bonded. Further, the intermolecular interaction may be generated by a van der Waals force between alkyl chains and π-δ stacking between aromatic rings.

Alkanethiol which may form the self assembled monolayers chemically reacts to the copper-clad layer 10 to form the surface-treated layer 20 and serves as a surfactant to prevent an agglomeration between metal particles.

As such, a thickness of a molecular film may become very small by using the method of forming the self assembled monolayer (SAM) of alkanethiol and the surface of the copper-clad layer 10 is chemically formed with a chemically reactive conjugated compound to be able to greater contribute to improvement in adhesive properties.

Alkanethiol derivatives may form the SAMs having various characteristics depending to on a structural difference, such as thiol or disulfide, an alkyl chain length, an end functional group, and containing of oligoethyleneglycol.

For example, it is known that the self assembled monolayers formed in the thiol or disulfide derivatives in the copper (Cu) have the same structure. In the case of taking the same Cu—S structure, hydrogen may be generated in the thiol and there may be an obscure fact, such as the absence of the detected example, Since a molecular weight of the thiol is about a half of that of the disulfide, the thiol has more excellent solubility, such that the thiol may be frequently used. However, the difference between the thiol and the disulfide is that when the end functional group is reactive to the thiol (active ester and maleimide), the disulfide needs to be used.

Due to the effect of the alkyl chain length, as the alkyl chain length becomes long, the stability of the formed self assembled monolayer may be improved. It is shown that as the alkyl chain length becomes long, adsorption species hardly deviates from a metal electrode and the self assembled monolayers are stably formed. Further, it is known that the alkyl chain length greatly affects even the case of measuring the movement of electrons using the self assembled monolayers.

Meanwhile, the properties of the self assembled monolayers may be controlled only by “mixed self assembled monolayers” which uses a plurality of other derivatives. In connection with a process of forming the self assembled monolayers and an orientation structure thereof, surface plasmon resonance (SPR), quartz oscillator microbalance (QCM), cyclic voltammetry (CV), and the like have been reviewed.

As described above, the surface-treated copper foil 1 according to the one implementation embodiment of the present invention may show an anchor effort without treating the roughed surface by forming the surface-treated layer 20 including the thiol-based compound on the copper-clad layer 10.

FIG. 3 is a diagram illustrating a copper-clad laminate plate according to one implementation embodiment of the present invention. Herein, to avoid the overlapping description, the descriptions of FIGS. 1 and 2 will be cited.

Referring to FIG. 3, a copper-clad laminate plate 3 according to the one implementation embodiment of the present invention may include a carrier 30, a peel layer 40 which is formed on the carrier 30, the copper-clad layer 10 which is formed on the peel layer 40, and the surface-treated layer 20 which is formed on the copper-clad layer 10.

The carrier 30 may be made of polymer, metal, or the like. The carrier 30 may serve as a stiffener for preventing a wrinkle of the copper-clad layer 10.

When the carrier 30 is made of polymer, a thickness of the carrier 30 may be formed to have a thickness of 15 to 200 μm. When the thickness of the copper-clad layer 10 is less than 15 μm, handling may not be easy and when the thickness of the copper-clad layer 10 exceeds 200 μm, the thickness is increased and thus thinness may not be implemented.

The carrier 30 made of the polymer may be selected from, for example, at least one of poly(ethyleneterephthalate) (PET), poly(phenylenesulfide) (PPS), Teflon, and fluorine containing film.

Further, the carrier 30 made of the metal may be made of metal which may form a release interface. For example, as the metal, any one selected from copper (Cu), aluminum (Al), and an alloy made of a combination thereof may be used. In this case, the thickness of the carrier 30 made of the metal may range from 10 to 30 μm. When the thickness of the carrier 30 is less than 10 μm, a function capable of supporting the copper-clad layer 10 may not be implemented and when the thickness of the carrier 30 exceeds 30 μm, the copper-clad layer may not be easily peeled during a peeling process performed later.

The peel layer 40 may be disposed to be interposed between the copper-clad layer 10 and the carrier 30. The peel layer 40 may be made of a treating agent selected from a silicon-based compound, an azole-based compound, or a mixture thereof.

For example, the peel layer 40 made of the silicon-based compound may be formed by surface-treating one surface of the carrier 30 with any one selected from Si and SiO₂, and a combination thereof. Further, the peel layer 40 using the azole-based compound may be formed by surface-treating one surface of the carrier 30 with any one selected from benzotriazole, tolytriazole, mercapto benzothiazole, imidazoles, and a mixture thereof.

As such, a peel strength may be stabilized at a low level by forming the peel layer 40 with the silicon-based compound, the azole-based compound, or a mixture thereof. Here, the peel layer 40 may be formed on the carrier 30 to have a thickness of several nm by being surface-treated.

The peel layer 40 may be formed by an immersion method, a showering method, a spray method, and the like which are typically used, but a method for forming the peel layer 40 is not particularly limited. To meet a process design, a method of most uniformly contacting a solution including silicon to the copper-clad layer 10 and adsorbing it may be arbitrarily adopted.

The copper-clad layer 10 may be made of copper and the thickness thereof may range from 0.1 μm to 5 μm. When the copper-clad layer 10 is less than 0.1 μm, microporosity may occur on the copper-clad layer 10 and when the copper-clad layer 10 exceeds 5 μm, the copper-clad layer 10 may not have required basic qualities.

The copper-clad layer 10 may be formed by using sputter, electronic beam, chemical vapor deposition (CVD), physical vapor deposition (PVD), vacuum deposition, ion plating, plasma deposition, and the like.

As described above, the copper-clad layer 10 is formed by the deposition method, not by the plating method, such that the thin copper foil may be formed and there is no need to recover a plating solution. The deposition method is a method of evaporating a deposition material at high temperature, adsorbing a material to a surface of adsorbed material, and coating a solid material thereon.

Describing briefly the sputter and the electron beam deposition as an example, when for example, copper which is a raw material of the thin film is used the sputter, the sputter has an advantage in increasing particle energy of the copper and increasing the adhesive force to a sample (for example, a substrate or a base and the copper-clad layer 10 in the implementation embodiment of the present invention). Further, the sputter may form a film without changing a composition ratio regardless of alloys, compound, and the like and may uniformly form a film with less distortion and deviation even when the film is formed in a large area.

Further, in the case of the electron beam deposition, molecular energy is small and thus the adhesive force is slightly weak and at the time of evaporation, the case in which composition is changed may occur but the film is formed under high vacuum, thereby forming a high purity thin film. Further, the electron beam deposition has a fast film forming speed.

As such the copper-clad layer 10 may be formed by a method meeting the conditions among the above-mentioned methods. Herein, in peeling the copper-clad layer 10 from the peel layer 40 later, the electron beam deposition method may simpler perform the easy peel.

The copper-clad layer used in the prior art is formed by an electrolysis method, not by the deposition method as described above, such that it is difficult to control a thickness of the copper-clad layer and to secure the adhesive force to the base while implementing the fine pattern, the thickness of the copper-clad layer needs to be set to be equal to or more than 18 μm. The reason is that to secure the adhesive force, the roughed surface (rugged surface) is formed on the copper-clad layer or the base to form the anchor.

However, according to one implementation embodiment of the present invention, a fine circuit pattern and a fine pitch may be implemented by forming the surface-treated layer 20, on which the chemical anchor may be formed, on the copper-clad layer 10, without forming the roughed surface.

The surface-treated layer 20 is formed by surface-treating the surface of the copper-clad to layer 10. The surface-treated layer 20 is formed by adsorbing the thiol-based compound onto the surface of the copper-clad layer 10. As such, the surface-treated layer 20 may improve the wettability with the surface of the copper-clad layer 10 which does not suffer from the roughening.

As described above, in the copper-clad laminate plate 3 according to the one implementation embodiment of the present invention, the surface-treated layer 20 is formed on the copper-clad layer 10 to forming the chemical adhesive force, thereby improving the adhesive force without the process of forming a roughed surface and the copper-clad layer 10 is formed by the sputter deposition, the electronic beam deposition, and the like, not by the plating method, thereby forming the thin copper-clad layer.

Therefore, the thin copper-clad layer may be formed by chemically improving the adhesive force of the copper foil without performing the roughening on the surface-treating layer 20, and thus may be formed to be suitable for the copper-clad laminate plate 3 for the circuit material.

FIG. 4 is a diagram illustrating a printed circuit board according to one implementation embodiment of the present invention. Herein, in order to avoid the overlapping description, the printed circuit board will be described with reference to FIGS. 1 to 3.

Referring to FIG. 4, a printed circuit board 4 according to the one implementation embodiment of the present invention includes an insulating layer 400, a surface-treated layer 420 which is formed on the insulating layer 400, and a circuit pattern 410 which is formed on the surface-treated layer 420, in which the surface-treated layer 420 may include the thiol-based compound.

The insulating layer 400 may be an insulating film, a prepreg (PPG), and a build-up film which serves to insulate between the circuit layers, in which the outermost sides thereof may be made of an insulating material (for example, photoresist), but are not particularly limited thereto.

Further, the printed circuit board 4 according to the one implementation embodiment of the present invention may be formed to include an inorganic filler, and the like, in the insulating layer 400 in consideration of a coefficient of thermal expansion characteristic.

The insulating layer 400 may be made of a material showing an insulating characteristic, for example, epoxy resin, in which the epoxy resin used as the insulating material is at least one selected from naphthalene-based epoxy resin, bisphenol A type epoxy resin, phenol novolac epoxy resin, cresol novolac epoxy resin, rubber modified epoxy resin, phosphate epoxy resin, and bisphenol F type epoxy resin.

The circuit pattern 410 may be formed on the insulating layer 400 and a thickness thereof may range from 0.1 μm to 5 μm.

For example, the circuit pattern 410 may adhere and be integrated on the insulating layer 400 by adhering the copper-clad laminate plate 3 on the insulating layer 400 and pressing/heating it and peeling the carrier 30 and the peel layer 40 of the copper-clad laminate plate 3. Here, since the copper-clad laminate plate 3 includes the peel layer 40 which is formed between the carrier 30 and the copper-clad layer 10, the carrier 30 may be easily peeled on the copper-clad layer 10.

Further, the circuit pattern 410 may be formed by patterning (etching) the copper-clad layer 10 which is exposed by the peel of the carrier 30. Here, describing the patterning by way of example, a process of forming a photoresist layer on the copper-clad layer 10 and exposing the photoresist layer is performed. Here, to perform the exposure process, an exposure region and a light blocking region are divided by using a mask having a shape corresponding to a circuit pattern. Further, the photoresist layer which is divided into the exposure region or the light blocking region is divided into a cured region and a non-cured region and regions remaining and removed by developing the non-cured/cured photoresist layer may be formed. As such, a mask pattern may be formed by using the remaining region. In this case, the copper-clad layer 10 is exposed in the region from which the mask pattern is removed and when the exposed copper-clad layer 10 is removed by an etchant and the mask pattern is removed, the circuit pattern 410 may be formed in the shape in which a portion of the copper-clad layer 10 remains.

In addition, the surface-treated layer 420 may be formed between the circuit pattern 410 and the insulating layer 400. The surface-treated layer 420 may be also formed by the above-mentioned etching method of the surface-treated layer 20 as illustrated in FIG. 3. The surface-treated layer 420 may improve the wettability with the surface of the surface of the circuit pattern 410 which does not suffer from the roughening. The surface-treated layer 420 may serve as an assistant for improving adhesion at the time of performing press machining on the insulating layer 400. Further, the peel strength of the surface-treated layer and the insulating layer may be 0.6 kgf/cm or more.

As such, the surface-treated layer 420 does not suffer from the roughening to be able to secure the stable adhesive force between the circuit pattern 410 and the insulating layer 400 and the printed circuit board 4 having the circuit pattern 410 formed to have the possible fine pattern and fine pitch by not forming the roughed surface may be formed.

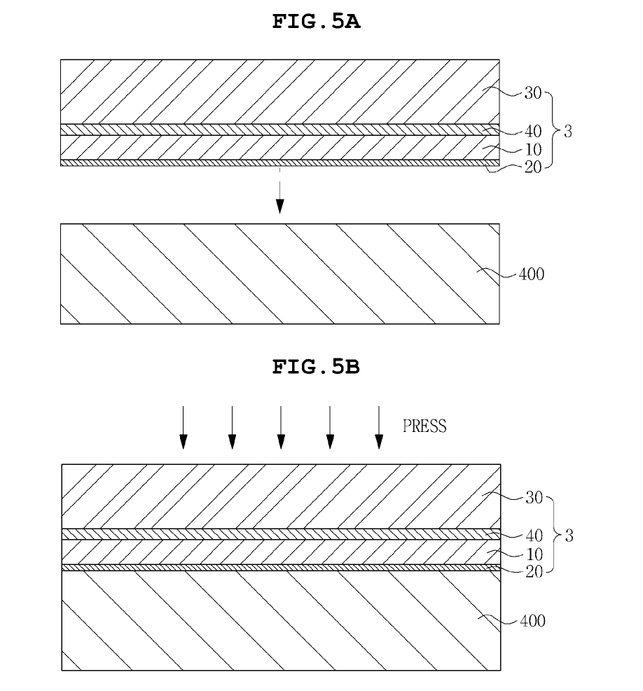

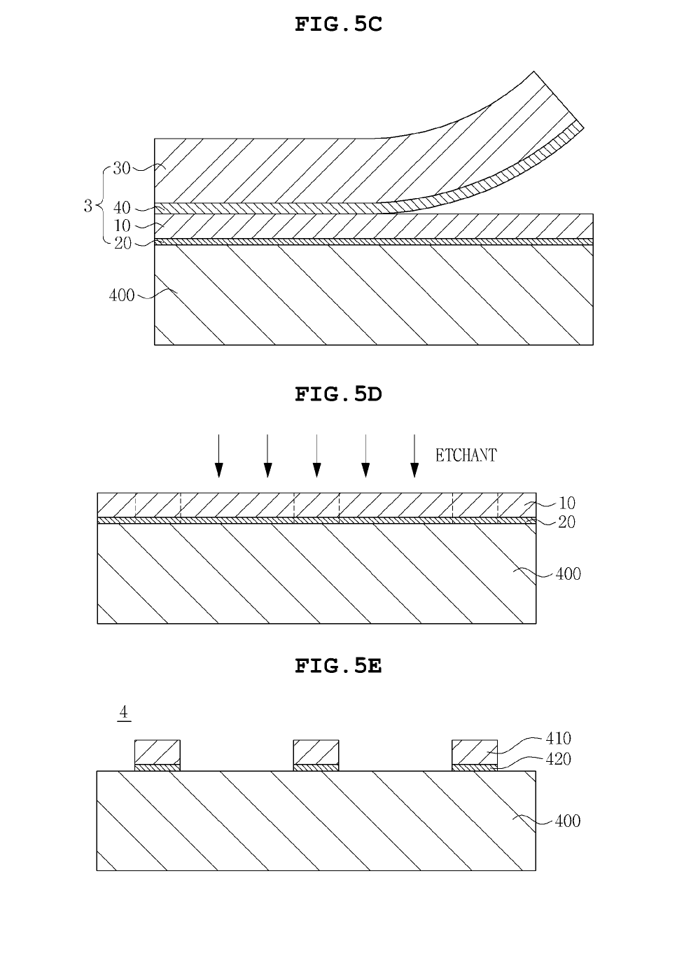

FIGS. 5A to 5E are process diagrams illustrating a method for manufacturing a printed circuit board according to one implementation embodiment of the present invention. In order to avoid the overlapping description, the method for manufacturing a printed circuit board will be described with reference to FIGS. 1 to 4.

Referring to FIG. 5A, the method for manufacturing a printed circuit board according to one implementation embodiment of the present invention may include adhering the insulating layer 400 to the copper-clad laminate plate 3 which includes the carrier 30, the peel layer 40, the copper-clad layer 10, and the surface-treated layer 20.

The carrier 30 may be made of polymer or metals forming the copper-clad layer 10 and a release interface. When the carrier 30 is made of polymer, the thickness of the carrier 30 may range from 15 to 200 μm and when the release interface may be made of metals such as copper, aluminum, or a combination thereof, the thickness of the carrier 30 may range from 10 to 30 μm.

The peel layer 40 may be formed on the carrier 30 and may be made of a solution including a silicon-based compound, an azole-based compound, or a combination thereof by a process selected from any one of the immersion method, the showering method, and the spray method.

The copper-clad layer 10 may be formed on the peel layer 40 and may be formed by a process selected from any one of the sputter, the electronic beam, the chemical vapor deposition (CVD), the physical vapor deposition (PVD), the vacuum deposition, the ion plating, and the plasma deposition. Further, the thickness of the copper-clad layer 10 may range from 0.1 to 5 μm.

The surface-treated layer 20 may be formed on the surface of the copper-clad layer 10 and may include the thiol-based compound. The copper-clad laminate plate 3 may be formed by the same method.

The insulating layer 400 may be prepreg which is prepared by impregnating the insulating film including epoxy resin, the build-up film, or the glass fiber.

Referring to FIG. 5B, according to the method for manufacturing a printed circuit board according to one implementation embodiment of the present invention, the copper-clad laminate plate 3 may adhere and be pressed on the insulating layer 400.

According to the printed circuit board manufactured according to the one implementation embodiment of the present invention, the circuit layer may be formed as a film and the adhesive strength between the insulating layer and the circuit layer may also be improved.

The insulating layer 400 and the surface-treated layer 20 may adhere and be pressed to each other by pressing the surface of the carrier 30 of the copper-clad laminate plate 3. The insulating layer 400 and the copper-clad laminate plate 3 may adhere and be integrated by adhering and pressing the insulating layer 400 and the copper-clad laminate plate 3.

Referring to FIG. 5C, the method for manufacturing a printed circuit board according to the one implementation embodiment of the present invention may include peeling the carrier 30 of the copper-clad laminate plate 3 using the peel layer 40 in the state in which the insulating layer 400 and the copper-clad laminate plate 3 are adhered/integrated. Here, the peel layer 40 is made of the silicon-based compound, the azole-based compound, and the like and thus may be stabilized at a level at which the peel strength is low. As such, the peel layer 40 is formed of a low peel strength and thus the carrier 30 is easily peeled from the copper-clad laminate plate 3.

Referring to FIG. 5D, the method for manufacturing a printed circuit board according to the one implementation embodiment of the present invention may include patterning the copper-clad layer 10 and the surface-treated layer 20 of which the surfaces are exposed by peeling the carrier 30 and the peel layer 40.

The circuit pattern may be formed by patterning the exposed copper-clad layer 10. Although not illustrated in FIG. 5D, the general photoresist known to those skilled in the art may be applied on the copper-clad layer 10 and a portion of the applied photoresist film may be subjected to the exposure and developing processes, and the like to form the opening. Next, the exposed copper-clad layer 10 and surface-treated layer 20 are etched by applying the etchant to the region in which the opening is formed so as to form the circuit pattern 410 and the surface-treated layer 420, such that the patterned circuit pattern may be formed. Further, the surface-treated layer 420 may adhere to the insulating layer 400.

Referring to FIG. 5E, according to the method for manufacturing a printed circuit board according to the one implementation embodiment of the present invention, the circuit pattern 410 may be formed by patterning the copper-clad layer 10. Further, in the patterning, the photoresist remaining on the circuit pattern 410 may also be removed.

At the same time, in the patterning, the surface-treated layer 20 formed beneath the copper-clad layer 10 may also be patterned to form the surface-treated layer 420. As such, the printed circuit board 4 may be formed using the copper-clad laminate plate 3. Further, the peel strength between the surface-treated layer 420 and the insulating layer 400 of the printed circuit board may be 0.6 kgf/cm or more.

Hereinafter, the present invention will be described in more detail with reference to Examples and Comparative Examples but the scope of the present invention is limited to the following Examples.

### Example 1

The carrier (PET) having a thickness of 100 μm was prepared and the peel layer was formed on one surface of the PET. The peel layer was surface-treated using Si and thus was formed as the peel layer having a thickness of 500 nm. The peel layer was formed by mixing silicon to have a concentration of 5 g/l using ion exchange water as a solvent. The mixed solution was adsorbed to the surface of the PET by the showering method. Next, a drier evaporates moisture within the atmosphere in which the surface temperature becomes 150° C. for 4 seconds to prepare a sample in which the peel layer is formed on the carrier.

Next, the sample was prepared in a DC magnetron sputter apparatus. Next, a copper target was prepared as a target and the DC magnetron sputter apparatus performs RF plasma treatment thereon at a pressure of 50 mtorr and an output density of 0.14 W/cm² for 3 minutes. Separated copper ions are adsorbed to the peel layer of the sample using the sputtering deposition to form the copper-clad layer having a thickness of 1 μm.

To form the surface-treated layer on the surface of the copper-clad layer, the surface-treated layer was formed by dipping the copper-clad layer in the phosphate solution of to Cystamine dihydrochloride of 0.1 moles (M) for 30 minutes, thereby manufacturing the copper-clad laminate plate.

### Example 2

Except that the surface-treated layer was formed by dipping the copper-clad layer in the phosphate solution of cystamine dihydrochloride of 0.1 moles (M) for 1 hour, Example 2 manufactured the copper-clad laminate plate under the same condition as Example 1.

### Example 3

Except that the surface-treated layer was formed by dipping the copper-clad layer in the phosphate solution of cystamine dihydrochloride of 0.1 moles (M) for 3 hours, Example 2 manufactured the copper-clad laminate plate under the same condition as Example 1.

### Example 4

The carrier (copper foil) having a thickness of 18 μm was prepared and the peel layer was formed on one surface of the copper foil. The peel layer was surface-treated using benzotriazole and thus was formed as the peel layer having a thickness of 200 nm. The peel layer was formed by mixing benzotriazole to have a concentration of 5 g/l using ion exchange water as a solvent. The mixed solution was adsorbed to the surface of the copper foil by the showering method. Next, a drier evaporates moisture within the atmosphere in which the surface temperature becomes 150° C. for 4 seconds to prepare a sample in which the peel layer is formed on the carrier.

Next, the sample was prepared in an electronic beam deposition apparatus. Next, in the electronic beam deposition apparatus, a copper target was prepared as a target. Here, a chamber was injected with argon (Ar) as inert gas until a vacuum diagram of the chamber is from 5.0×10⁻⁶ torr at the beginning to 2.0×10⁻⁵ torr. Separated copper ions are adsorbed to the peel layer of the sample using the electronic beam deposition apparatus to form the copper-clad layer having a thickness of 1 μm.

To form the surface-treated layer on the surface of the copper-clad layer, the copper-clad layer was dipped in the acetone solution of cystamine dihydrochloride of 0.1 moles (M). Next, the surface-treated layer was formed by dipping the copper-clad layer in the acetone solution for 2 minutes, thereby manufacturing the copper-clad laminate plate.

### Example 5

Except that the surface-treated layer was formed by dipping the copper-clad layer in the acetone solution of cystine of 0.1 moles (M) for 5 minutes, Example 2 manufactured the copper-clad laminate plate under the same condition as Example 4.

### Example 6

Except that the surface-treated layer was formed by dipping the copper-clad layer in the acetone solution of cystine of 0.1 moles (M) for 30 minutes, Example 2 manufactured the copper-clad laminate plate under the same condition as Example 4.

### Comparative Example 1

The sample including the copper-clad layer formed on the carrier manufactured by Example 1 was prepared. Next, the copper-clad laminate plate in which the surface-treated layer is not formed on the copper-clad layer of the sample was manufactured.

### Comparative Example 2

The sample including the copper-clad layer formed on the carrier manufactured by Example 4 was prepared. Next, the surface-treated layer was formed by dipping the copper-clad layer of the sample in the acetone solution of cystine of 0.1 mole (M) for 2 minutes and the copper-clad laminate plate was manufactured by performing desmear treatment on the copper-clad layer and the surface-treated layer.

### Example 7

### Manufacturing of Printed Circuit Board

The printed circuit board was manufactured by performing the vacuum laminating on the copper-clad laminate plate manufactured by Examples 3 and 6 on both surfaces of the insulating base (insulating layer) including the epoxy resin under the temperature of 90° C. and the pressure condition of 2 MPa for 20 seconds using a Morton CVA 725 vacuum laminate.

Measuring Physical Properties

Evaluation of physical properties of the copper-clad laminate plate manufactured with Examples 1 to 6 and Comparative Examples 1 and 2 was shown in the following Table 1. The samples were cut in the state in which the copper-clad layer and the insulating layer to manufactured by the above Examples and Comparative Examples adhere and are integrated and the peel strength was measured at the measurement sample width of 10 mm based on a method defined in JISC6511 by peel the copper foil from the adhering/integrated copper-clad layer and insulating layer. The peel strength of the copper-clad layer and the insulating layer was measured and evaluated by a universal testing machine (UTM).

TABLE 1

| | | Presence and absence |
|---|---|---|
| Division | Peel strength (kgf/cm) | of circuit layer |
| Example 1 | 0.36 | Presence |
| Example 2 | 0.51 | Presence |
| Example 3 | 0.68 | Presence |
| Example 4 | 0.43 | Presence |
| Example 5 | 0.60 | Presence |
| Example 6 | 0.69 | Presence |
| Comparative | No measurement | Absence |
| Example 1 | | |
| Comparative | No measurement | Absence |
| Example 2 | | |

As can be appreciated from Table 1, the adhesive force is more excellent in Example 3 than in Examples 1 and 2 and it may be appreciated that the adhesive force of Example 6 is more excellent than in Examples 3 and 4 formed of metal. Meanwhile, Comparative Examples 1 and 2 show the adhesive force which may hardly be measured. In Examples 3 and 6, it may be appreciated that the chemical anchor may be formed by the sufficient adsorption time and the measurement value was measured at 0.6 kgf/cm or more which is suitable to be used as the adhesive layer.

According to the surface-treated copper foil, the copper-clad laminate plate including the same, the printed circuit board using the same, and the method for manufacturing the same to according to the implementation embodiments of the present invention, the adhesive strength between the base and the copper-clad layer may be improved without treating the roughed surface by forming the surface-treated layer on the copper-clad layer, thereby improving the reliability of the printed circuit board having the circuit pattern.

Various features and advantages of the present invention will be more obvious from the following description with reference to the accompanying drawings.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A surface-treated copper foil, comprising:
a copper-clad layer; and
a surface-treated layer formed on the copper-clad layer.

2. The surface-treated copper foil as set forth in claim 1, wherein a thickness of the copper-clad layer ranges from 0.1 μm to 5 μm.

3. The surface-treated copper foil as set forth in claim 1, wherein the surface-treated layer includes a thiol-based compound.

4. A copper-clad laminate plate, comprising:
a carrier;
a peel layer formed on the carrier;
a copper-clad layer formed on the peel layer; and
a surface-treated layer formed on the copper-clad layer.

5. The copper-clad laminate plate as set forth in claim 4, wherein the carrier is made of polymer or metal forming the copper-clad layer and a release interface.

6. The copper-clad laminate plate as set forth in claim 5, wherein the carrier made of polymer is selected from poly (ethyleneterephthalate) (PET), poly (phenylenesulfide) (PPS), Teflon, and fluorine containing film.

7. The copper-clad laminate plate as set forth in claim 5, wherein a thickness of the carrier made of the polymer ranges from 15 μm to 200 μm.

8. The copper-clad laminate plate as set forth in claim 5, wherein the carrier made of the metals is selected from copper, aluminum, or a combination thereof.

9. The copper-clad laminate plate as set forth in claim 5, wherein the thickness of the carrier made of the metal ranges from 10 μm to 30 μm.

10. The copper-clad laminate plate as set forth in claim 4, wherein the peel layer is selected from a silicon-based compound, an azole-based compound, or a mixture thereof.

11. The copper-clad laminate plate as set forth in claim 4, wherein the thickness of the copper-clad layer ranges from 0.1 to 5 μm.

12. The copper-clad laminate plate as set forth in claim 4, wherein the surface-treated layer includes a thiol-based compound.

13. A printed circuit board, comprising:
an insulating layer;
a surface-treated layer formed on the insulating layer; and
a circuit pattern formed on the surface-treated layer.

14. The printed circuit board as set forth in claim 13, wherein the surface-treated layer includes a thiol-based compound.

15. The printed circuit board as set forth in claim 13, wherein a thickness of the circuit pattern ranges from 0.1 μm to 5 μm.

16. The printed circuit board as set forth in claim 13, wherein a peel strength of the surface-treated layer and the insulating layer is 0.6 kgf/cm or more.

17. The printed circuit board as set forth in claim 13, wherein an epoxy resin used for the insulating layer is at least one selected from naphthalene-based epoxy resin, bisphenol A type epoxy resin, phenol novolac epoxy resin, cresol novolac epoxy resin, rubber modified epoxy resin, phosphate epoxy resin, and bisphenol F type epoxy resin.

18. A method for manufacturing a printed circuit board, comprising:
adhering an insulating layer to a copper-clad laminate plate including a carrier, a peel layer, a copper-clad layer, and a surface-treated layer;
peeling the carrier and the peel layer of the copper-clad laminate plate; and
patterning the copper-clad layer and the surface-treated layer of the copper-clad laminate plate.

19. The method as set forth in claim 18, wherein the patterning of the copper-clad layer and the surface-treated layer of the copper-clad laminate plate includes:
applying a resist on the copper-clad layer;
forming an opening by exposing and developing a portion of the applied resist film; and
etching the copper-clad layer and the surface-treated layer of an area in which the opening is formed.

20. The method as set forth in claim 18, wherein the copper-clad layer is formed by at least any one process selected from sputter, electronic beam, chemical vapor deposition (CVD), physical vapor deposition (PVD), vacuum deposition, ion plating, and plasma deposition.

21. The method as set forth in claim 18, wherein the peel layer is made of a solution including a silicon-based compound, an azole-based compound, or a combination thereof from a process selected by any one of an immersion method, a showering method, and a spray method.

22. The method as set forth in claim 18, wherein a thickness of the copper-clad layer ranges from 0.1 μm to 5 μm.

23. The method as set forth in claim 18, wherein a peel strength of the surface-treated layer and the insulating layer is 0.6 kgf/cm or more.
